(19) United States
(12) Patent Application Publication
(10) Pub. No.: US 2023/0421135 A1
(43) Pub. Date: Dec. 28, 2023

(54) MODULATION DEVICE

(71) Applicant: Innolux Corporation, Miaoli County (TW)

(72) Inventors: Chia-Ping Tseng, Miaoli County (TW); Yan-Zheng Wu, Miaoli County (TW)

(73) Assignee: Innolux Corporation, Miaoli County (TW)

(21) Appl. No.: 18/325,083

(22) Filed: May 29, 2023

Related U.S. Application Data
(60) Provisional application No. 63/356,038, filed on Jun. 28, 2022.

(30) Foreign Application Priority Data
Mar. 16, 2023 (CN) 202310254054.X

(51) Int. Cl. H03H 11/24; H01L 27/12; H01L 23/58

(52) U.S. Cl. CPC H03H 11/245; H01L 23/585; H01L 27/1255

(57) ABSTRACT

A modulation device includes a substrate, a metal layer, at least one driving element, and a modulation unit. The metal layer is disposed on the substrate and has at least one hole. The at least one driving element is disposed on the substrate and overlapped with the at least one hole. The modulation unit is electrically connected to the at least one driving element.

### CROSS-REFERENCE TO RELATED APPLICATION

This application claims the priority benefit of U.S. provisional application Ser. No. 63/356,038, filed on Jun. 28, 2022 and China application serial no. 202310254054.X, filed on Mar. 16, 2023. The entirety of each of the above-mentioned patent applications is hereby incorporated by reference herein and made a part of this specification.

### BACKGROUND

### Technical Field

The disclosure relates to an electronic device, and more particularly, to a modulation device.

### Description of Related Art

During the manufacture of an electronic device, ions in the metal layer on the substrate tend to diffuse to the upper element area, resulting in degradation of element characteristics. In addition, the grain roughness of the semiconductor layer in the element may be increased by the roughness of the underlying metal layer, resulting in reduced carrier mobility. In addition, the element is readily electrically coupled with the underlying metal layer, resulting in threshold voltage shift.

### SUMMARY

The disclosure provides a modulation device that may improve the influence of a metal layer on a driving element.

In an embodiment of the disclosure, a modulation device includes a substrate, a metal layer, at least one driving element, and a modulation unit. The metal layer is disposed on the substrate and has at least one hole. The at least one driving element is disposed on the substrate and overlapped with the at least one hole. The modulation unit is electrically connected to the at least one driving element.

In another embodiment of the disclosure, a modulation device includes a substrate, a metal layer, at least one driving element, and a modulation unit. The metal layer is disposed on the substrate and includes a first portion and a second portion, wherein a thickness of the first portion is greater than a thickness of the second portion. The at least one driving element is disposed on the substrate and overlapped with the second portion. The modulation unit is electrically connected to the at least one driving element.

In order to make the aforementioned features and advantages of the disclosure more comprehensible, embodiments accompanied with figures are described in detail below.

### BRIEF DESCRIPTION OF THE DRAWINGS

FIG. 1 is a schematic partial top view of a modulation device according to an embodiment of the disclosure.

FIG. 2 is a schematic cross-sectional view of section line A-A′ in FIG. 1.

FIG. 3 to FIG. 5 are partial schematic cross-sectional views of modulation devices according to some other embodiments of the disclosure.

FIG. 6 to FIG. 10 are schematic partial top views of modulation devices according to some further embodiments of the disclosure.

### DESCRIPTION OF THE EMBODIMENTS

Hereinafter, exemplary embodiments of the disclosure are described in detail, and examples of the exemplary embodiments are conveyed via the figures. Wherever possible, the same reference numerals are used in the figures and the descriptions to refer to the same or similar portions.

Certain terms are used throughout the specification and attached claims of the disclosure to refer to particular elements. Those having ordinary skill in the art should understand that manufacturers of electronic devices may refer to the same element with different names. The specification does not intend to distinguish between elements having the same function but different names. In the following specification and claims, words such as “comprising” and “including” are open-ended words, so they should be interpreted as meaning “comprising but not limited to . . . ”

The directional terms mentioned herein, such as “upper”, “lower”, “front”, “rear”, “left”, “right”, etc., refer to directions in the drawings. Accordingly, the directional terms used are for illustration, not for limiting the disclosure. In the drawings, each figure illustrates the general characteristics of methods, structures, and/or materials used in particular embodiments. However, these drawings should not be interpreted as defining or limiting the scope or nature encompassed by these embodiments. For example, the relative dimensions, thicknesses, and positions of layers, regions, and/or structures may be reduced or exaggerated for clarity.

A structure (or layer, element, substrate) described in the disclosure as being located on/over another structure (or layer, element, substrate) may mean that the two structures are adjacent and directly connected, or it may mean that the two structures are adjacent rather than directly connected. Indirect connection means that there is at least one intermediate structure (or intermediate layer, intermediate element, intermediate substrate, intermediate space) between the two structures. The lower surface of one structure is adjacent to or directly connected to the upper surface of the intermediate structure, and the upper surface of the other structure is adjacent to or directly connected to the lower surface of the intermediate structure. The intermediate structure may be formed by a single-layer or multi-layer physical structure or non-physical structure without limitation. In the disclosure, when a structure is disposed “on” other structures, it may mean that a certain structure is “directly” on the other structures, or that a certain structure is “indirectly” on the other structures, that is, there is at least one structure interposed between the certain structure and the other structures.

The terms “about”, “substantially”, or “essentially” are generally interpreted as being within 10% of a given value or range, or as being within 5%, 3%, 2%, 1%, or 0.5% of a given value or range.

Words such as “first” and “second” used in the specification and claims are used to modify elements, which do not themselves imply and represent that the (or these) elements have any previous ordinal numbers, nor do they imply an order of a certain element with another element, or an order in manufacturing methods. These ordinal numbers are used to clearly distinguish an element having a certain designation from another element having the same designation. The same wording may be not used in the claims and the specification. Accordingly, a first member in the specification may be a second member in the claims.

The electrical connection or coupling described in the disclosure may both refer to direct connection or indirect connection. In the case of direct connection, the terminals of elements on two circuits are connected directly or to each other by a conductor segment. In the case of indirect connection, there is a switch, a diode, a capacitor, an inductor, a resistor, other suitable elements, or a combination of the above elements between the terminals of the elements on the two circuits, but the disclosure is not limited thereto.

In the disclosure, the thickness, length, and width may be measured by using an optical microscope (OM), and the thickness or width may be measured by a cross-sectional image in an electron microscope, but the disclosure is not limited thereto. In addition, any two values or directions used for comparison may have a certain error. Moreover, the phrases “the given range is from a first value to a second value” and “the given range falls within the range from a first value to a second value” mean that the given range includes the first value, the second value, and other values in between. If a first direction is perpendicular to a second direction, the angle between the first direction and the second direction may be between 80 degrees and 100 degrees. If the first direction is parallel to the second direction, the angle between the first direction and the second direction may be between 0° and 10°.

It should be noted that, in the following embodiments, without departing from the spirit of the disclosure, features in several different embodiments may be replaced, reorganized, and mixed to complete other embodiments. As long as the features of the various embodiments do not violate the spirit of the disclosure or conflict each other, they may be mixed and matched arbitrarily.

Unless otherwise defined, all terms (including technical and scientific terms) used herein have the same meaning as commonly understood by those having ordinary skill in the art to which this disclosure belongs. It may be understood that these terms, such as those defined in commonly used dictionaries, should be interpreted as having a meaning consistent with the background or context of related techniques and the disclosure, and should not be interpreted in an idealized or overly formal manner, unless otherwise defined in the embodiments of the disclosure.

In the disclosure, an electronic device may include a display device, a backlight device, a radio-frequency device, a sensing device, or a tiling device, but the disclosure is not limited thereto. The electronic device may be a bendable or flexible electronic device. The display device may be a non-self-luminous display device or a self-luminous display device. The radio-frequency device may include a frequency-selective surface (FSS), a radio-frequency filter (RF-filter), a polarizer, a resonator, or an antenna, etc. The antenna may be a liquid-crystal type antenna or a non-liquid-crystal type antenna. The sensing device may be a sensing device for sensing capacitance, light, heat, or ultrasound, but the disclosure is not limited thereto. The electronic element may include a passive element and an active element, such as a capacitor, a resistor, an inductor, a diode, a transistor, and the like. The diode may include a light-emitting diode or a photodiode. The light-emitting diode may include, for example, an organic light-emitting diode (OLED), a mini LED, a micro LED, or a quantum dot LED, but the disclosure is not limited thereto. The tiling device may be, for example, a display tiling device or a radio-frequency tiling device, but the disclosure is not limited thereto. It should be noted that the electronic device may be any arrangement and combination of the above, but the disclosure is not limited thereto. In the following, the radio-frequency device is used as the electronic device to illustrate the content of the disclosure, but the disclosure is not limited thereto.

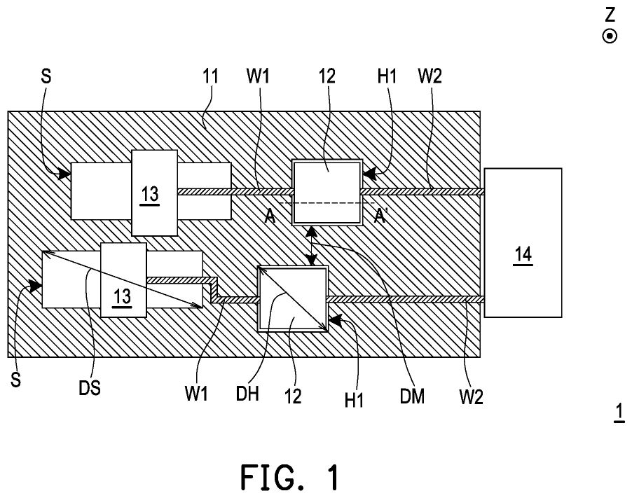

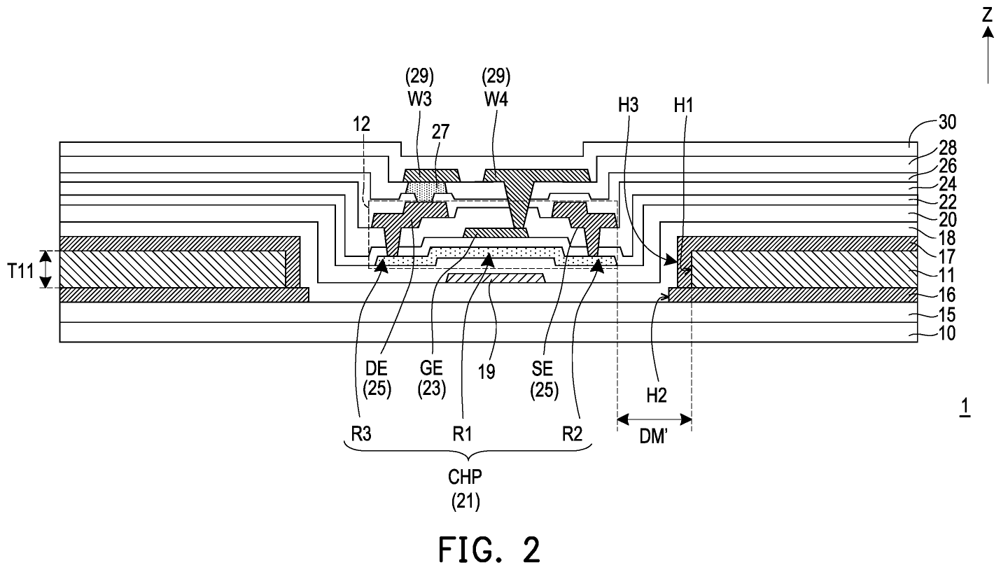

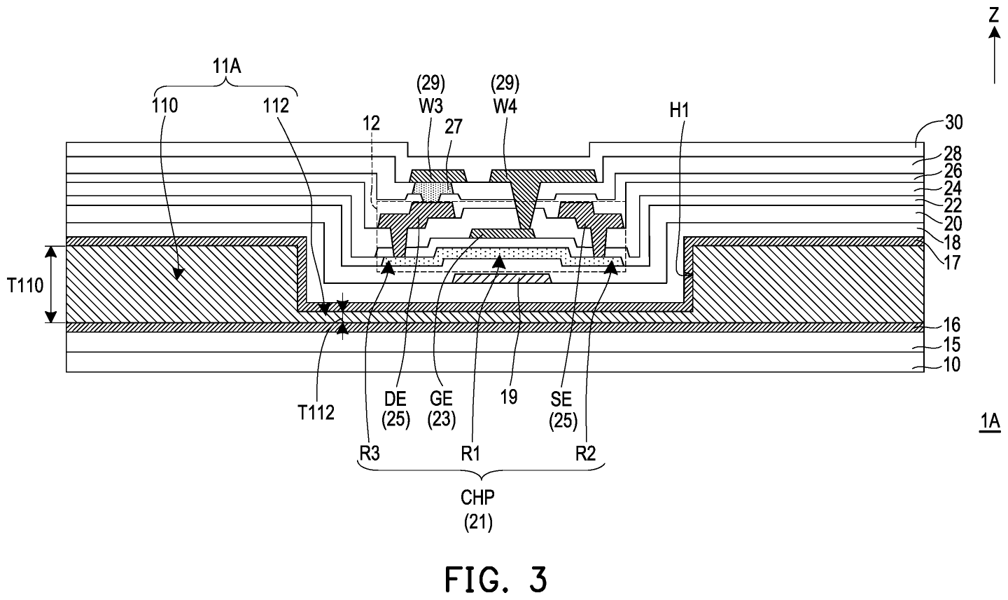

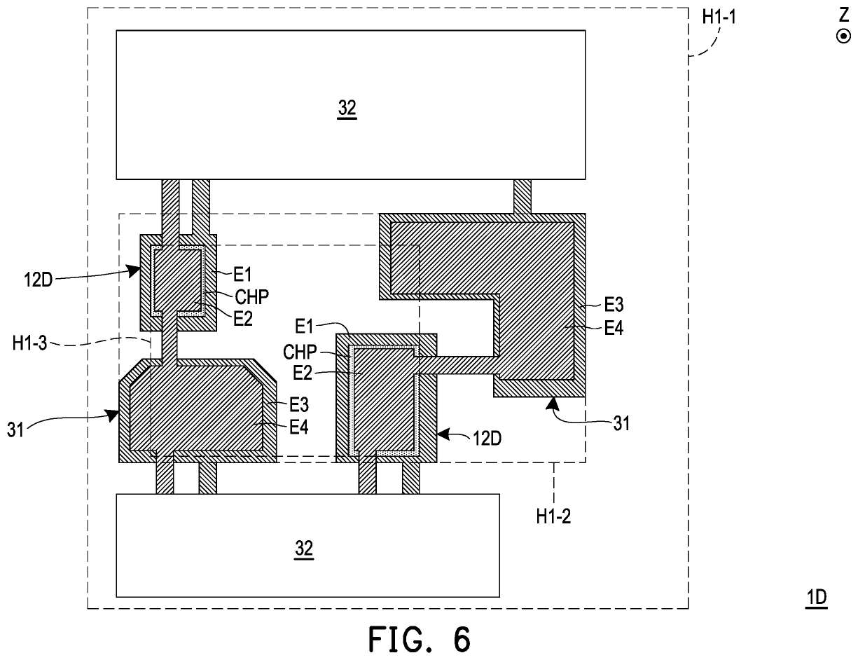

FIG. 1 is a schematic partial top view of a modulation device according to an embodiment of the disclosure. FIG. 2 is a schematic cross-sectional view of section line A-A′ in FIG. 1. FIG. 3 to FIG. 5 are partial schematic cross-sectional views of modulation devices according to some other embodiments of the disclosure. FIG. 6 to FIG. 10 are schematic partial top views of modulation devices according to some further embodiments of the disclosure.

Referring to FIG. 1 and FIG. 2, a modulation device 1 may include a substrate a metal layer 11, at least one driving element 12, and a modulation unit 13. The metal layer 11 is disposed on the substrate 10 and has at least one hole H1. The at least one driving element 12 is disposed on the substrate 10 and overlapped with the at least one hole H1. The modulation unit 13 is electrically connected to the at least one driving element 12.

In detail, the substrate 10 may be used to carry an element. In some embodiments, the substrate 10 may also be used as a waveguide structure transmitting an electromagnetic wave, but the disclosure is not limited thereto. In other embodiments, the waveguide structure may be replaced by a transmission line or a free space. The substrate 10 may be a rigid substrate or a flexible substrate. For example, the material of the substrate 10 may include glass, polymer film (such as polyimide film), printed circuit board, or a combination thereof, but the disclosure is not limited thereto.

The metal layer 11 may be used to limit the output area of the electromagnetic wave passing thereunder, for example, the electromagnetic wave may be output from an area not covered by the metal layer 11. For example, the material of the metal layer 11 may include copper, aluminum, silver, gold, any material having high conductivity, or a combination thereof, but the disclosure is not limited thereto.

In some embodiments, based on considerations such as manufacturing process or electromagnetic wave shielding, a thickness T11 of the metal layer 11 is between 0.5 μm and 2 μm, that is, 0.5 μm≤T11≤12 μm, but the disclosure is not limited thereto. The thickness T11 of the metal layer 11 is the maximum thickness of the metal layer 11 in the thickness direction (e.g., direction Z) of the modulation device 1 viewed from the cross section of the modulation device 1.

The hole H1 of the metal layer 11 may be a through hole or a blind hole, that is, the hole H1 may be where the metal layer 11 is hollowed out (as shown in FIG. 2) or where the metal layer 11 is thinned (as shown in FIG. 3). The hole H1 may accommodate the driving element 12. In some embodiments, the hole H1 may be partially overlapped with the driving element 12. In some embodiments, a dimension DH of the hole H1 may be greater than 4 μm and less than 3 cm, so as to facilitate the arrangement of the driving element 12 and/or reduce the possibility of electromagnetic waves escaping from the hole H1. The dimension DH of the hole H1 is the maximum dimension of the hole H1 viewed from the top of the modulation device 1. Taking the quadrilateral hole H1 as an example, the dimension DH of the hole H1 may be the diagonal width of the hole H1.

By disposing the driving element 12 in the hole H1 of the metal layer 11, the driving element 12 may be not overlapped with the metal layer 11 in the direction Z. In this way, the issue that the ions (such as copper ions) in the metal layer 11 diffuse to the element area (such as the area where the driving element 12 is located) during the high-temperature process and resulting in the degradation of element characteristics may be alleviated, the influence of the roughness of the metal layer 11 on the carrier mobility of the driving element 12 is reduced, or the influence of the metal layer 11 on the threshold voltage of the driving element 12 is reduced, etc.

FIG. 1 schematically shows two holes H1 and two driving elements 12, and each of the driving elements 12 is disposed in one corresponding hole H1, but it should be understood that, the number of the holes H1, the number of the driving elements 12, and/or the number of the driving elements 12 in each of the holes H1 may be changed according to requirements, and is not limited thereto. For example, the metal layer 11 may include more or less holes H1; the modulation device may include more or less driving elements 12; and/or each of the holes H1 may be provided with a plurality of driving elements 12. Moreover, based on process capability and/or other considerations, in an embodiment in which the metal layer 11 includes a plurality of holes H1, a minimum distance DM between two adjacent holes H1 may be greater than 3.5 μm, but the disclosure is not limited thereto.

In some embodiments, the metal layer 11 may further include at least one slot S. The slot S is, for example, where the metal layer 11 is hollowed out. The slot S may be used to allow an electromagnetic wave to pass through. A dimension DS of the slot S may be determined by the frequency or wavelength of the electromagnetic wave. In some embodiments, the dimension DS of the slot S is less than 1 cm, but the disclosure is not limited thereto. In some embodiments, the dimension DS of the slot S falls within the range of 500 μm to 600 μm, that is, 500 μm≤DS≤600 μm, but the disclosure is not limited thereto. The dimension DS of the slot S is the maximum dimension of the slot S viewed from the top of the modulation device 1. Taking the quadrilateral slot S as an example, the dimension DS of the slot S may be the diagonal width of the slot S.

In some embodiments, as shown in FIG. 2, the at least one driving element 12 may include a thin-film transistor. The thin-film transistor may include a semiconductor pattern CHP, a gate GE, a source SE, and a drain DE. FIG. 2 schematically illustrates that the gate GE is located above the semiconductor pattern CHP. However, it should be understood that the relative arrangement relationship between the plurality of electrodes (such as the gate GE, the source SE, and the drain DE) and the semiconductor pattern CHP in the thin-film transistor may be changed according to actual requirements, and the disclosure is not limited thereto.

The modulation unit 13 is disposed on the substrate 10 and corresponding to the slot S, for example, that is, the modulation unit 13 and the slot S are overlapped at least partially in the direction Z. For example, the modulation unit 13 may traverse the slot S, and the modulation unit 13 may include a capacitor, a resistor, an inductor, a diode, a transistor, an MEMS, or a combination thereof. The relevant parameters of the modulation unit 13 may be modulated by a signal applied to the modulation unit 13. The relevant parameters may include dielectric constant, area, semiconductor depletion region width, metal plate height, etc., but the disclosure is not limited thereto. In some embodiments, the modulation unit 13 may package modulation components by techniques such as panel-level package (PLP), wafer-level package (WLP), or fan-out wafer-level package (FOWLP). In some embodiments, the modulation unit 13 may be bonded to one or a plurality of corresponding conductive patterns and/or signal lines by means of direct bonding, micro-bonding, or flip-chip bonding, for example.

In some embodiments, the modulation unit 13 may include a variable capacitor. The variable capacitor may be formed by a liquid-crystal device, a varactor diode, or a micro electro mechanical system (MEMS), etc., but the disclosure is not limited thereto. By changing the voltage applied to the variable capacitor, the equivalent capacitance in the radio-frequency circuit may be controlled, so that the phase and amplitude of the electromagnetic wave are changed accordingly, thereby controlling the direction of the electromagnetic wave or improving the directivity of the radio-frequency device.

The modulation unit 13 may be electrically connected to the at least one driving element 12 via a wire W1. FIG. 1 schematically shows two slots S, two modulation units 13, two wires W1, and two driving elements 12, wherein each of the modulation units 13 traverses one corresponding slot S and is electrically connected to one corresponding driving element 12 via one corresponding wire W1. However, it should be understood that the respective numbers and/or relative arrangement relationship of the slots S, the modulation units 13, the wires W1, and the driving elements 12 may be changed according to requirements, and the disclosure is not limited thereto.

According to different requirements, the modulation device 1 may also include other elements or layers. For example, as shown in FIG. 1, the modulation device 1 may further include an outer lead bonding (OLB) panel 14, and the OLB panel 14 may be electrically connected to the plurality of driving elements 12 via a plurality of wires W2.

In addition, as shown in FIG. 2, the modulation device 1 may further include a dielectric layer 15. The dielectric layer 15 is disposed on the substrate 10 and located, for example, between the metal layer 11 and the substrate 10 and between the driving element 12 and the substrate 10. For example, the material of the dielectric layer 15 may include an inorganic material such as silicon oxide, silicon nitride, or a combination thereof, but the disclosure is not limited thereto.

In some embodiments, the modulation device 1 may further include a conductive layer 16. The conductive layer 16 is disposed on the dielectric layer 15 and, for example, located between the metal layer 11 and the dielectric layer 15. The conductive layer 16 may be used, for example, to improve the adhesion between the metal layer 11 and the dielectric layer 15 or as a buffer layer of coefficient of thermal expansion (CTE). For example, the material of the conductive layer 16 may include a metal, such as titanium, but the disclosure is not limited thereto.

The conductive layer 16 may have a hole H2. The hole H2 is disposed corresponding to the hole H1 and the at least one driving element 12, that is, the hole H2 is at least partially overlapped with the hole H1 and the at least one driving element 12 in the direction Z.

The metal layer 11 is disposed on the conductive layer 16, and the modulation device 1 may further include a conductive layer 17. The conductive layer 17 is disposed on the metal layer 11 and the conductive layer 16. The conductive layer 17 may be used, for example, to improve the adhesion between the metal layer 11 and the upper film layer (such as a dielectric layer 18) thereof or as a buffer layer of CTE. For example, the material of the conductive layer 17 may include a metal, such as titanium, but the disclosure is not limited thereto.

The conductive layer 17 may have a hole H3. The hole H3 is disposed corresponding to the hole H2, the hole H1, and the at least one driving element 12, that is, the hole H3 is at least partially overlapped with the hole H2, the hole H1, and the at least one driving element 12 in the direction Z.

The modulation device 1 may further include the dielectric layer 18. The dielectric layer 18 is disposed on the conductive layer 17, the conductive layer 16, and the dielectric layer 15. For example, the material of the dielectric layer 18 may include an inorganic material such as silicon oxide, silicon nitride, or a combination thereof, but the disclosure is not limited thereto.

The modulation device 1 may further include a light-shielding layer 19. The light-shielding layer 19 is disposed on the dielectric layer 18 and, for example, located between the at least one driving element 12 and the dielectric layer 18. For example, the material of the light-shielding layer 19 may include a metal, an alloy, other light-reflecting materials or light-absorbing materials. The light-shielding layer 19 is overlapped with at least a channel region R1 of the semiconductor pattern CHP in the direction Z, so as to reduce the interference of light (such as ambient light) on the channel region R1.

The modulation device 1 may further include a dielectric layer 20. The dielectric layer 20 is disposed on the dielectric layer 18 and the light-shielding layer 19. For example, the material of the dielectric layer 20 may include an inorganic material such as silicon oxide, silicon nitride, or a combination thereof, but the disclosure is not limited thereto.

The modulation device 1 may further include a semiconductor layer 21. The semiconductor layer 21 is disposed on the dielectric layer 20. For example, the material of the semiconductor layer 21 may include amorphous silicon, polysilicon, metal oxide, or a combination thereof, but the disclosure is not limited thereto. The metal oxide includes, for example, indium gallium zinc oxide (IGZO), but the disclosure is not limited thereto. The semiconductor layer 21 may be a patterned semiconductor layer and may include a plurality of semiconductor patterns CHP (only one is schematically shown in FIG. 2). The semiconductor pattern CHP may include the channel region R1, a source region R2, and a drain region R3, and the channel region R1 is located between the source region R2 and the drain region R3.

Based on considerations of process capability, process parameters, precision, etc., under the architecture in which the at least one driving element 12 includes a thin-film transistor, a minimum distance DM′ between the semiconductor pattern CHP of the thin-film transistor and the metal layer 11 is greater than 3 μm, for example, but the disclosure is not limited thereto. The minimum distance DM′ is the minimum distance in the lateral direction from the sidewall of the hole H1 of the metal layer 11 to the outermost edge of the semiconductor pattern CHP viewed from the cross section of the modulation device 1.

The modulation device 1 may further include a dielectric layer 22. The dielectric layer 22 is disposed on the dielectric layer 20 and the semiconductor layer 21. For example, the material of the dielectric layer 22 may include an inorganic material such as silicon oxide, silicon nitride, or a combination thereof, but the disclosure is not limited thereto.

The modulation device 1 may further include a conductive layer 23. The conductive layer 23 is disposed on the dielectric layer 22. For example, the material of the conductive layer 23 may include a metal or a metal stack, such as titanium, aluminum, molybdenum, or a combination thereof, but the disclosure is not limited thereto. The conductive layer 23 may be a patterned conductive layer, and the conductive layer 23 may include a gate GE, a gate line (not shown), and other circuits (not shown), but the disclosure is not limited thereto.

The modulation device 1 may further include a dielectric layer 24. The dielectric layer 24 is disposed on the dielectric layer 22 and the conductive layer 23. For example, the material of the dielectric layer 24 may include an inorganic material such as silicon oxide, silicon nitride, or a combination thereof, but the disclosure is not limited thereto.

The modulation device 1 may further include a conductive layer 25. The conductive layer 25 is disposed on the dielectric layer 24. For example, the material of the conductive layer 25 may include a metal or a metal stack, such as titanium, aluminum, molybdenum, or a combination thereof, but the disclosure is not limited thereto. The conductive layer 25 may be a patterned conductive layer, and the conductive layer 25 may include the source SE, the drain DE, a data line (not shown), the wire W1 (see FIG. 1), the wire W2 (see FIG. 1), and other circuits (not shown), but the disclosure is not limited thereto. The source SE may penetrate through the dielectric layer 24 and the dielectric layer 22 to be electrically connected to the source region R2. The drain DE may penetrate through the dielectric layer 24 and the dielectric layer 22 to be electrically connected to the drain region R3. In other embodiments, although not shown, the wire W1 (see FIG. 1) and the wire W2 (see FIG. 1) may be not in the same layer as the source SE, the drain DE, and the data line (not shown).

The modulation device 1 may further include a dielectric layer 26. The dielectric layer 26 is disposed on the dielectric layer 24 and the conductive layer 25. For example, the material of the dielectric layer 26 may include an inorganic material such as silicon oxide, silicon nitride, or a combination thereof, but the disclosure is not limited thereto.

The modulation device 1 may further include a transparent conductive layer 27. The transparent conductive layer 27 is disposed on the dielectric layer 26 and located, for example, on the drain DE of the at least one driving element 12. For example, the material of the transparent conductive layer 27 may include metal oxide, graphene, other suitable transparent conductive materials, or a combination thereof. The metal oxide may include indium tin oxide, indium zinc oxide, aluminum tin oxide, aluminum zinc oxide, indium germanium zinc oxide, or other metal oxides. The transparent conductive layer 27 may be a patterned conductive layer, and the transparent conductive layer 27 may penetrate through the dielectric layer 26 to be electrically connected to the drain electrode DE. In this way, the modulation unit 13 may be electrically connected to the at least one driving element 12 via the transparent conductive layer 27.

The modulation device 1 may further include a dielectric layer 28. The dielectric layer 28 is disposed on the dielectric layer 26 and surrounds the transparent conductive layer 27. For example, the material of the dielectric layer 28 may include an inorganic material such as silicon oxide, silicon nitride, or a combination thereof, but the disclosure is not limited thereto.

The modulation device 1 may further include a conductive layer 29. The conductive layer 29 is disposed on the dielectric layer 28. For example, the material of the conductive layer 29 may include a metal or a metal stack, such as titanium, aluminum, molybdenum, or a combination thereof, but the disclosure is not limited thereto. The conductive layer 29 may be a patterned conductive layer, and the conductive layer 29 may include a wire W3, a wire W4, and other circuits (not shown), but the disclosure is not limited thereto. The wire W3 may be disposed on the transparent conductive layer 27 and electrically connected to the transparent conductive layer 27. The wire W4 may penetrate through the dielectric layer 28, the dielectric layer 26, and the dielectric layer 24 to be electrically connected to the gate GE.

The modulation device 1 may further include a dielectric layer 30. The dielectric layer 30 is disposed on the dielectric layer 28 and the conductive layer 29. For example, the material of the dielectric layer 30 may include an inorganic material such as silicon oxide, silicon nitride, or a combination thereof, but the disclosure is not limited thereto.

Although not shown, the modulation device 1 may also include other passive elements or active elements (such as integrated circuits or light-emitting elements, etc.), and the above elements may penetrate through the dielectric layer 30 to be electrically connected to the wire W3 and the wire W4.

Please refer to FIG. 3, the modulation unit is not shown in a modulation device 1A, and the details of the modulation unit are as provided in the related description of FIG. 1, which are not repeated herein. The main difference between the modulation device 1A and the modulation device 1 shown in FIG. 1 and FIG. 2 is that a metal layer 11A in the modulation device 1A includes a first portion 110 and a second portion 112, wherein a thickness T110 of the first portion 110 is greater than a thickness T112 of the second portion 112, and the at least one driving element 12 is overlapped with the second portion 112.

By thinning the second portion 11 in the metal layer 11A overlapped with the at least one driving element 12, the influence of the metal layer 11A on the driving element 12 may be alleviated. In some embodiments, the ratio range of the thickness T110 to the thickness T112 may be less than 1/2 and greater than or equal to 1/5, and the ratio range may be, for example, 1/3, 1/4, or other suitable ratio ranges, but the disclosure is not limited thereto. For example, the thickness T110 of the first portion 110 may be less than four times the thickness T112 of the second portion 112, but the disclosure is not limited thereto.

Although not shown in FIG. 3, the metal layer 11A may also include the slot S shown in FIG. 1, and the modulation unit (refer to FIG. 1) may be overlapped with the slot S. The metal layer in any embodiment of the disclosure may be changed accordingly, and is therefore not repeated below.

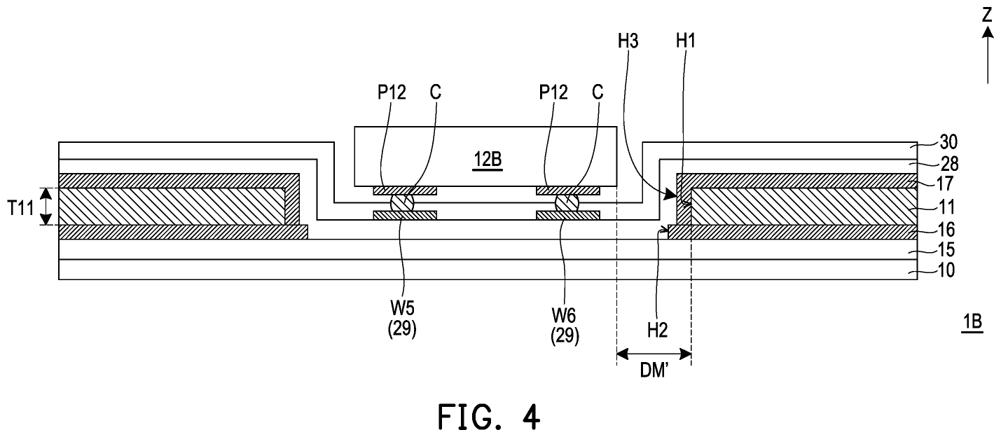

Please refer to FIG. 4, a modulation unit is not shown in a modulation device 1B, and the details of the modulation unit are as provided in the related description of FIG. 1, which are not repeated herein. The main differences between the modulation device 1B and the modulation device 1 shown in FIG. 1 and FIG. 2 are described as follows.

In the modulation device 1B, at least one driving element 12B includes an integrated circuit, and the minimum distance DM′ between the integrated circuit and the metal layer 11 is greater than 3 μm, for example. The minimum distance DM′ is the minimum distance in the first direction (for example: X direction) from the sidewall of the hole H1 of the metal layer 11 to the adjacent side of the driving element 12B viewed from the cross section of the modulation device 1B. Moreover, a plurality of pads P12 of the driving element 12B are respectively electrically connected to a plurality of wires (such as a wire W5 and a wire W6) in the conductive layer 29 via a plurality of conductive members C, for example, but the disclosure is not limited thereto. In other unillustrated embodiments, the wire W5 and the wire W6 may be on the same layer as the source SE and the drain DE in FIG. 2. The conductive members C may include conductive bumps (such as solder balls), conductive adhesive, or anisotropic conductive film (ACF), but the disclosure is not limited thereto.

Moreover, although not shown in FIG. 4, the modulation device 1B may also include at least one of the dielectric layer 18, the light-shielding layer 19, the dielectric layer 20, the semiconductor layer 21, the dielectric layer 22, the conductive layer 23, the dielectric layer 24, the conductive layer 25, the dielectric layer 26, and the transparent conductive layer 27 in FIG. 2.

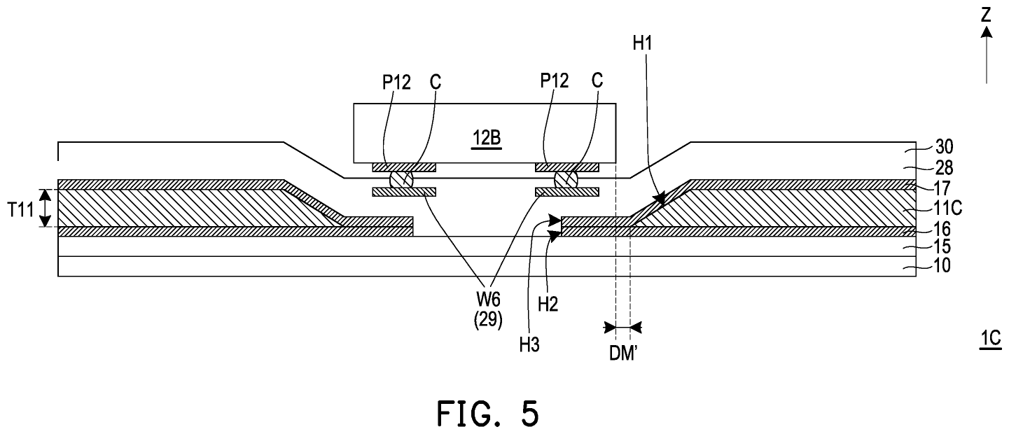

Please refer to FIG. 5, a modulation unit is not shown in a modulation device 1C, and the details of the modulation unit are as provided in the related description of FIG. 1, which are not repeated herein. The main differences between the modulation device 1C and the modulation device 1B of FIG. 4 are described as follows.

In the modulation device 1C, the sidewall of the hole H1 of the metal layer 11C is inclined relative to the substrate 10, and the conductive layer 16 and the conductive layer 17 are extended below the at least one driving element 12B, so that the at least one driving element 12B is overlapped with a portion of the conductive layer 16 and a portion of the conductive layer 17.

Please refer to FIG. 6, a substrate, a metal layer, and a modulation unit are not shown in a modulation device 1D. For the details of the above elements, please refer to the relevant descriptions of FIG. 1 or FIG. 2, which are not repeated herein.

The modulation device 1D may include one or a plurality of driving elements 12D, one or a plurality of capacitive elements 31, and one or a plurality of circuits 32 (such as testing circuits or repairing circuits), wherein the one or plurality of circuits 32 are electrically connected to the one or plurality of driving elements 12D and/or the one or plurality of capacitive elements 31. FIG. 6 schematically shows an electrode E1, the semiconductor pattern CHP, and an electrode E2 in each of the driving elements 12D, and schematically shows an electrode E3 and an electrode E4 in each of the capacitive elements 31. However, it should be understood that each of the driving element 12D and the capacitive element 31 may further include other elements or layers.

The dimension and/or shape of the holes in the metal layer may be changed according to actual needs. For example, the hole in the metal layer (shown as a hole H1-1) may also accommodate the one or plurality of capacitive elements 31 and the one or plurality of circuits 32 (such as test circuits or repair circuits) in addition to the one or plurality of drive elements 12D. Alternately, the range of the hole (shown as a hole H1-2) may be defined according to the largest rectangle formed by a plurality of electrodes (such as a plurality of electrodes E4) in the one or plurality of driving elements 12D and/or the one or plurality of capacitive elements 31. Alternatively, the range of the hole (shown as a hole H1-3) may be defined according to the largest rectangle formed by the plurality of semiconductor patterns CHP in the one or plurality of driving elements 12D.

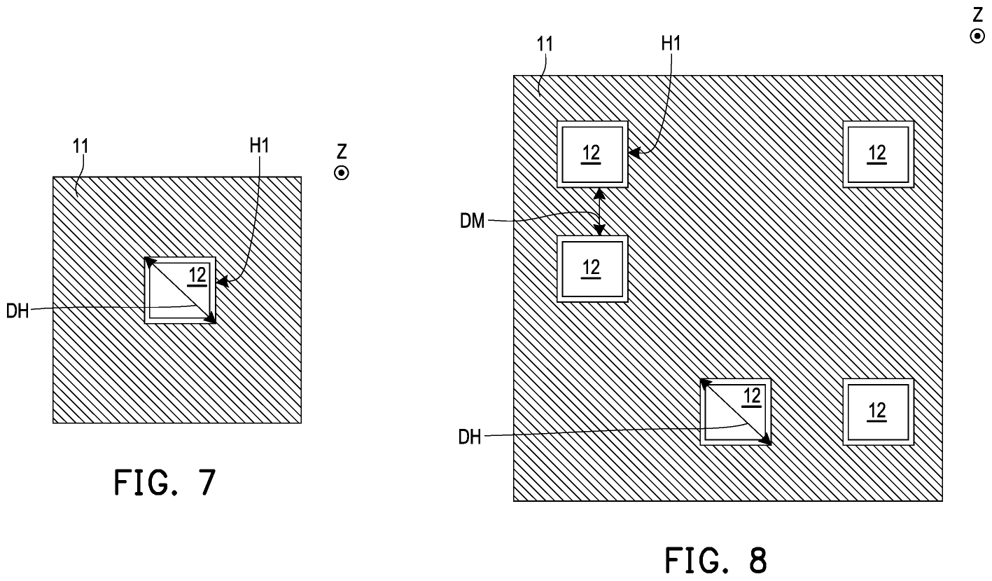

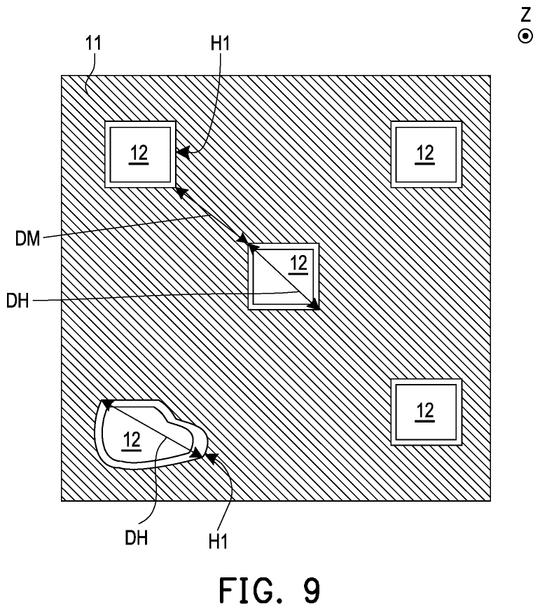

The shape, quantity, and/or distribution of the holes in the metal layer may also be changed according to actual needs. As shown in FIG. 7, the number of the hole H1 in the metal layer 11 may be one. In addition, the shape (top view shape) of the hole H1 may be a rectangle for ease of manufacture, but the disclosure is not limited thereto. As shown in FIG. 8, the number of the hole H1 in the metal layer 11 may be plural, and the plurality of holes H1 may be disposed corresponding to the plurality of driving elements 12 (such as including thin-film transistors or integrated circuits). That is, the plurality of holes H1 are at least partially overlapped with the plurality of driving elements 12 in the direction Z. In addition, the plurality of holes H1 may be arranged in a regular manner or in an irregular manner. As shown in FIG. 9, the shape of the at least one hole H1 in the metal layer 11 may be an irregular shape (see the hole H1 in the lower left corner).

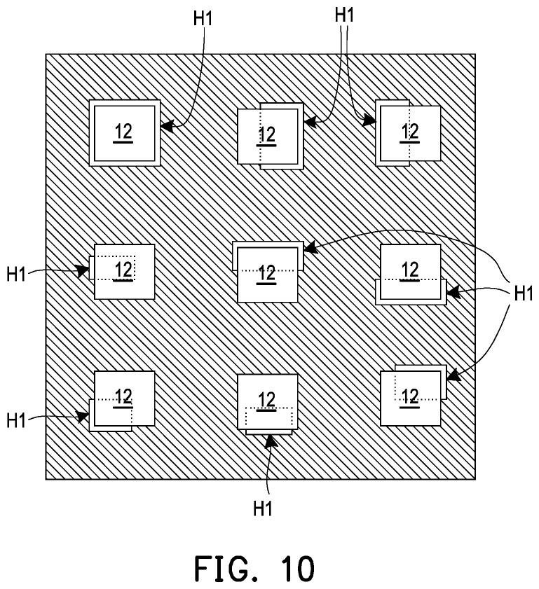

Specifically, the shape of the holes H1 may be the same as the shape of the integrated circuits or the shape of the semiconductor patterns in the thin-film transistor, so as to reduce the influence on the characteristic performance of the element. In some embodiments, when viewed from the top, the at least one hole H1 may have a curved edge, but the disclosure is not limited thereto. As shown in FIG. 10, the area of the at least one hole H1 in the metal layer 11 may be less than the area of the driving element 12.

Based on the above, in an embodiment of the disclosure, by removing or thinning at least a portion of the metal layer overlapped with the driving element, the negative impact of the metal layer on the driving element may be alleviated.

The above embodiments are used to illustrate the technical solution of the disclosure, not to limit them. Although the disclosure has been described in detail with reference to the above embodiments, those having ordinary skill in the art should understand that: it is still possible to modify the technical solutions recited in the above embodiments, or perform equivalent replacements for some or all of the technical features. However, these modifications or replacements do not make the essence of the corresponding technical solutions depart from the scope of the technical solutions of the embodiments of the disclosure.

Although the embodiments of the disclosure and the advantages thereof are disclosed above, it should be understood that, anyone having ordinary skill in the art, without departing from the spirit and scope of the disclosure, may modify, substitute, and polish, and the features of each embodiment may be arbitrarily mixed and replaced with each other to form other new embodiments. Moreover, the scope of protection of the disclosure is not limited to the processes, machines, manufactures, material compositions, devices, methods, and steps in the specific embodiments described in the specification. Anyone having ordinary skill in the art may understand the current or future developed processes, machines, manufactures, material compositions, devices, methods, and steps from the content disclosed in the disclosure, which may all be used according to the disclosure as long as substantially the same function may be implemented or substantially the same result may be obtained in the embodiments described herein. Therefore, the scope of protection of the disclosure includes the above processes, machines, manufactures, material compositions, devices, methods, and steps. In addition, each claim constitutes an individual embodiment, and the scope of protection of the disclosure also includes the combination of each claim and the embodiments. The scope of protection of the disclosure should be defined by the scope of the attached claims.

What is claimed is:

1. A modulation device, comprising:
a substrate;
a metal layer disposed on the substrate and having at least one hole;
at least one driving element disposed on the substrate and overlapped with the at least one hole; and
a modulation unit electrically connected to the at least one driving element.

2. The modulation device of claim 1, wherein a thickness of the metal layer is between 0.5 μm and 2 μm.

3. The modulation device of claim 1, further comprising:
a transparent conductive layer disposed on a drain of the at least one driving element, and the modulation unit is electrically connected to the at least one driving element via the transparent conductive layer.

4. The modulation device of claim 1, wherein the at least one driving element comprises a thin-film transistor, and a minimum distance between a semiconductor pattern of the thin-film transistor and the metal layer is greater than 3 μm.

5. The modulation device of claim 1, wherein the at least one driving element comprises an integrated circuit, and a minimum distance between the integrated circuit and the metal layer is greater than 3 μm.

6. The modulation device of claim 1, wherein a dimension of the at least one hole is greater than 4 μm and less than 3 cm.

7. The modulation device of claim 1, wherein the at least one hole comprises a plurality of holes, and a minimum distance between two adjacent holes is greater than 3.5 μm.

8. The modulation device of claim 1, wherein the metal layer further has a slot, and the modulation unit is at least partially overlapped with the slot.

9. The modulation device of claim 8, wherein the modulation unit traverses the slot.

10. The modulation device of claim 8, wherein a dimension of the slot falls within a range of 500 μm to 600 μm.

11. The modulation device of claim 1, further comprising:
at least one capacitive element, wherein the at least one hole accommodates the at least one driving element and the at least one capacitive element.

12. The modulation device of claim 11, wherein a range of the at least one hole is defined according to a largest rectangle formed by a plurality of electrodes in the at least one driving element and the at least one capacitive element.

13. The modulation device of claim 1, wherein the at least one driving element comprises a plurality of driving elements, and a range of the at least one hole is defined according to a largest rectangle formed by a plurality of semiconductor patterns in the plurality of driving elements.

14. A modulation device, comprising:
a substrate;
a metal layer disposed on the substrate and comprising a first portion and a second portion, wherein a thickness of the first portion is greater than a thickness of the second portion;
at least one driving element disposed on the substrate and overlapped with the second portion; and
a modulation unit electrically connected to the at least one driving element.

15. The modulation device of claim 14, wherein the thickness of the first portion is less than four times the thickness of the second portion.

16. The modulation device of claim 14, wherein the metal layer has a slot, and the modulation unit is overlapped with the slot.

17. The modulation device of claim 16, wherein the modulation unit traverses the slot.

18. The modulation device of claim 16, wherein a dimension of the slot falls within a range of 500 μm to 600 μm.

19. The modulation device of claim 14, wherein the at least one driving element comprises a thin-film transistor or an integrated circuit.

20. The modulation device of claim 14, further comprising:
a transparent conductive layer disposed on a drain of the at least one driving element, and the modulation unit is electrically connected to the at least one driving element via the transparent conductive layer.
